(19) United States
(12) Patent Application Publication
(10) Pub. No.: US 2007/0249121 A1
(43) Pub. Date: Oct. 25, 2007

(54) METHOD OF FABRICATING NON-VOLATILE MEMORY

(76) Inventors: Chien-Kang Kao, Hsinchu City (TW); Chia-Ming Kuo, Hsinchu County (TW); Chia-Lin Ku, Hsinchu Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,206

(22) Filed: Jul. 13, 2006

(30) Foreign Application Priority Data
Apr. 19, 2006 (TW) 95113898

(51) Int. Cl. H01L 21/336

(52) U.S. Cl. 438/264; 438/962; 977/774

(57) ABSTRACT

A method of fabricating a non-volatile memory is provided. The method includes providing a substrate. Next, a tunneling oxide layer is formed on the substrate and a surface nitridation process is performed to nitridize the upper surface of the tunneling oxide layer. A plurality of nanocrystals is formed on the nitridized surface of the tunneling oxide layer. Next, the surfaces of the nanocrystals are nitridized. An oxide layer and a conductive layer are formed in sequence over the tunneling oxide layer to cover the nanocrystals. Due to the formation of high-density nanocrystals as a charge storage medium, the properties of the memory are enhanced.

### CROSS-REFERENCE TO RELATED APPLICATION

This application claims the priority benefit of Taiwan application serial no. 95113898, filed on Apr. 19, 2006. All disclosure of the Taiwan application is incorporated herein by reference.

### BACKGROUND OF THE INVENTION

1. Field of the Invention

The present invention relates to a method of fabricating a non-volatile memory, and more particularly, to a method of fabricating a non-volatile memory having nano-dots as its charge storage medium.

2. Description of Related Art

Electrically erasable programmable read-only memory (EEPROM) is a type of non-volatile memory that allows multiple data writing, reading and erasing operations. Furthermore, the stored data will be retained even after power to the device is removed. With these advantages, EEPROM has been broadly applied to personal computers and electronic equipments.

A typical EEPROM has a floating gate and a control gate fabricated using doped polysilicon. To write data into the memory, electric charges are injected into the floating gate and then the electric charges are distributed evenly across the entire polysilicon gate layer. To erase data from the memory, the electric charges are drained from the floating gate. However, when the tunneling oxide layer underneath the polysilicon floating gate layer contains defects, current leakage occurs and thereby adversely affecting the reliability of the device. Moreover, while performing the erasing operation, the quantity of electrons expelled is difficult to control. As a result, an excess amount of electrons may be drained from the floating gate, leading to the so-called over-erase phenomenon and subsequent data judgment error. Thus, there are many aspects in the design of EEPROM to be improved.

In the past, manufacturers have developed several means of improving the design of a memory, including the use of nanocrystals as the charge storage medium. The design replaces the polysilicon floating gate in a conventional memory with nanocrystals composed of silicon so that electric charges are injected into the nanocrystals and are stored therein. Even though the tunneling oxide layer in the nanocrystal memory has a leakage pathway due to the presence of structural defects, a good charge retention capacity is maintained.

However, the volume of the nanocrystal grains and the density of crystal per unit area have a definite effect on the properties of the nanocrystal memory. For example, too large a grain size may lead to an excessive operating voltage while too low a crystal density may lead to the shifting of threshold voltage to a smaller value and narrowing of the memory window.

Moreover, there is a positive relationship between the number of crystals formed in the process of growing nanocrystals and the number of dangling bonds. In other words, the larger the number of dangling bonds, the easier it will be to form a large number of nanocrystals. In general, the nanocrystals are directly formed on the tunneling oxide layer, that is, the surface of the silicon oxide layer. Since fewer dangling bonds are formed on the surface of a silicon oxide layer, a chemical pre-treatment is typically performed to increase the number of dangling bonds on the surface of the tunneling oxide layer. However, the chemical pre-treatment may damage the surface of the tunneling oxide layer so that the thickness and uniformity of the tunneling oxide layer is difficult to control. Ultimately, an effective enhancement of the properties of the memory is virtually impossible.

Recent researches on nanocrystals have discovered the benefit of directly growing nanocrystals on a deposited silicon nitride layer. Refer to IEEE, IEDM 98-111 (Room Temperature Single Electron Effects in Si Quantum Dot Memory with Oxide-Nitride Tunneling Dielectrics) and IEEE, IEDM 98-136 (Fabrication of Silicon Quantum Dots on Oxide and Nitride). Although the surface of the silicon nitride layer has more dangling bonds, silicon nitride also has the capacity to store electric charges. If the silicon nitride layer is directly used as a tunneling layer in a device, the memory may have a discernable leakage current and a higher operating voltage. Therefore, the foregoing method needs further improvements.

### SUMMARY OF THE INVENTION

Accordingly, at least one objective of the present invention is to provide a method of fabricating a non-volatile memory for producing a nanocrystal non-volatile memory having a lower operating voltage and a higher threshold voltage shift.

At least another objective of the present invention is to provide a method of fabricating a charge storage layer for a non-volatile memory, by which the memory has a nanocrystal charge storage layer having a smaller crystal diameter and a higher crystal density.

To achieve these and other advantages and in accordance with the purpose of the invention, as embodied and broadly described herein, the invention provides a method of fabricating a non-volatile memory. The method includes providing a substrate. Then, a tunneling oxide layer is formed on the substrate. After that, a surface nitridation process is performed to nitridize the upper surface of the tunneling oxide layer. A plurality of nano-dots is formed on the nitridized surface of the tunneling oxide layer. Next, the surfaces of the nano-dots are nitridized. An oxide layer is formed over the surface of the tunneling oxide layer to cover the nano-dots. Finally, a conductive layer is formed on the surface of the oxide layer.

The present invention also provides a method of fabricating a charge storage layer for a non-volatile memory. The method includes providing a substrate having a tunneling oxide layer formed thereon. Then, a surface nitridation process is performed to nitridize the upper surface of the tunneling oxide layer. Finally, a plurality of nano-dots is formed on the nitridized tunneling oxide layer.

In the present invention, a nitridation process is performed to nitridize the surface of a tunneling oxide layer on a substrate and forms a base for growing nano-dots. Therefore, nanocrystals are grown on the nitridized surface to produce high-density nano-dots so that threshold voltage shift is increased and the properties of the memory are enhanced. Moreover, by forming an oxide layer on the substrate, leakage current resulting from a direct contact between the nitridation layer and the substrate is avoided.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1F are schematic cross-sectional views showing the steps for fabricating a non-volatile memory according to the preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

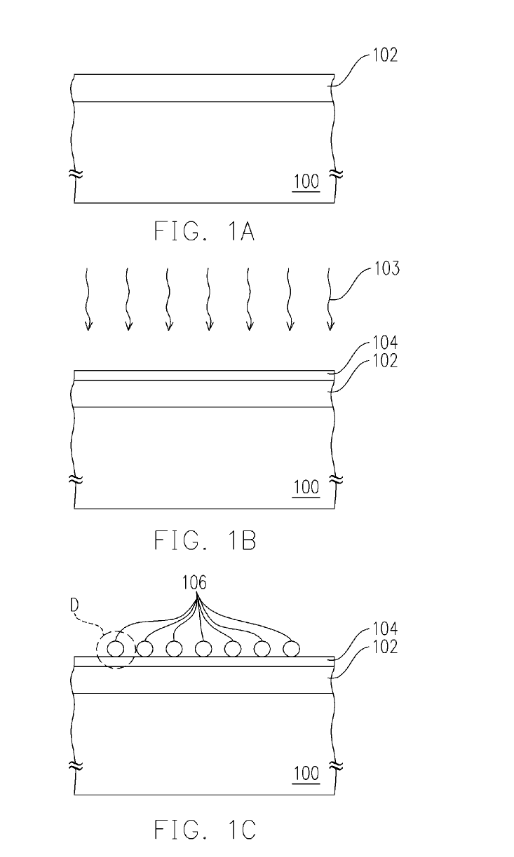

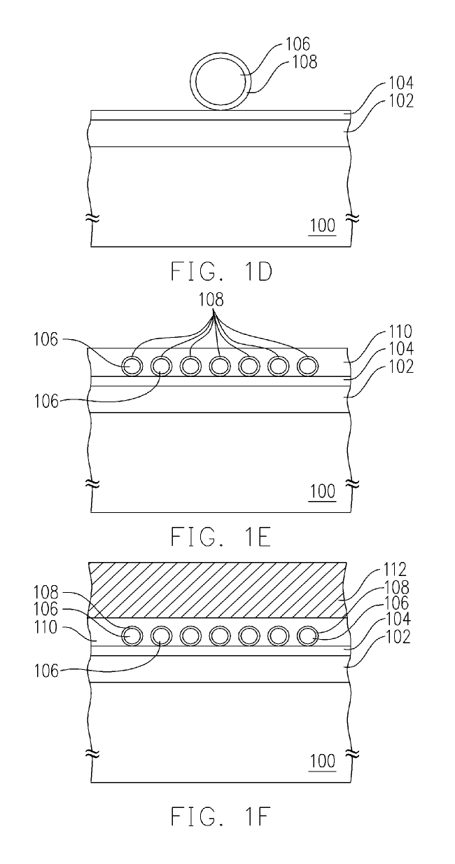

FIGS. 1A through 1F are schematic cross-sectional views showing the steps for fabricating a non-volatile memory according to the preferred embodiment of the present invention.

As shown in FIG. 1A, a tunneling oxide layer 102 is formed on a substrate 100. In general, a thermal oxidation process is performed to form the tunneling oxide layer 102. The substrate 100 is a silicon substrate and the tunneling oxide layer is fabricated using silicon oxide, for example.

As shown in FIG. 1B, a surface nitridation process 103 is performed to nitridize the upper surface of the tunneling oxide layer 102 into a nitridized surface 104 such as a oxy-nitride layer or a nitridized layer. The surface nitridation process 103 can be a thermal nitridation process or a plasma nitridation process. Because the thermal nitridation process can prevent so many nitrogen atoms from penetrating into the tunneling oxide layer 102 that affect the electrical properties (for example, inducing a larger leakage current) of the memory, it is selected as the preferred embodiment.

Again, as shown in FIG. 1B, when a thermal nitridation process is used as the surface nitridation process 103, the processing temperature is in a range of about 650° C. to 1000° C. and the nitridation period is in a range of about 10 minutes to 90 minutes, for example.

As shown in FIG. 1C, nano-dots 106 are formed on the upper surface 104 of the nitridized tunneling oxide layer 102. In this step, the nano-dots are fabricated using, for example, silicon (Si), germanium (Ge) or other material capable of forming nano-dots through grain growth. Because the surface 104 of the nitridized tunneling oxide layer 102 has a large number of dangling bonds, nanocrystals grow densely on the aforementioned surface 104 to produce a high-density nano-dot structure. The density of the nano-dots 106 is, for example, greater than 5×10¹¹ dots/cm², but preferably greater than 1×10¹² dots/cm². In the present embodiment, the nano-dots 106 have a particle size smaller than 5 nanometers (nm), for example.

The process up to this stage constitutes a method for fabricating the charge storage layer of a memory. Because the fabrication of the charge storage layer is one key aspect of improving the properties of the non-volatile memory in the present invention, it needs to be specified. Furthermore, a nitridation process on the surface of the tunneling oxide layer is performed to produce more dangling bonds so that high-density nanocrystals (nano-dots) are grown thereon. In addition, the nitridation process will not compromise the uniformity of the surface of the tunneling oxide layer. Moreover, compared with a deposition process, the nitridation process is capable of forming a thinner nitride layer or oxy-nitride layer on the tunneling oxide layer. As a result, the method not only increases the charge storage density, but also reduces the leakage current and operation voltage because it provides a thin tunneling oxide layer having a uniform nitridized upper surface with dangling bonds.

FIG. 1D is a sectional magnified view of the D portion of FIG. 1C. As shown in FIG. 1D, the surface of the nano-dots 106 is nitridized to form a thin protective layer 108. The process of forming the protective layer 108 on the surface of the nano-dots 106 includes exposing the nano-dots 106 in a nitrogen-containing gas, such as nitrogen gas, and heating to a temperature of about 300° C. to 650° C., for example. Typically, the protective layer 108 is fabricated using silicon nitride. One principal function of the protective layer 108 is to prevent the surface of nano-dots 106 from oxidation.

As shown in FIG. 1E, an oxide layer 110 is formed on the surface of the tunneling oxide layer 102 to cover the nano-dots 106. The method of forming the oxide layer 110 includes performing a chemical vapor deposition process, for example.

As shown in FIG. 1F, a conductive layer 112 is formed on the oxide layer 110 to serve as a control gate for the non-volatile memory. The conductive layer 112 can be a doped polysilicon layer, for example. Afterwards, other steps, such as doping/ion implantation processes, are subsequently carried out to complete the fabrication of a memory device.

In summary, the fabrication of nano-crystal non-volatile memory in the present invention involves growing nano-dots on the surface of a nitridized tunneling oxide layer, thereby eliminating the need to perform a conventional surface treatment of the tunneling oxide layer with chemicals before actually growing the nano-dots. Furthermore, the present invention may also reduce the possibility of high leakage current and operation voltage since the nano-dots are not grown directly on a deposited nitride layer according to the invention. Thus, compared with the nano-dots grown on a conventional oxide layer, the present invention not only increases the distribution density of nano-dots, but also decreases the particle size of nano-dots. Therefore, the threshold voltage shift is increased so that the memory window of the memory is effectively increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a non-volatile memory, comprising:
providing a substrate;
forming a tunneling oxide layer on the substrate;
performing a surface nitridation process to nitridize an upper surface of the tunneling oxide layer;
forming a plurality of nano-dots on an upper surface of the nitridized tunneling oxide layer;
nitridizing surfaces of the nano-dots;
forming an oxide layer over the nano-dots and the upper surface of the tunneling oxide layer; and
forming a conductive layer on the oxide layer.

2. The method of fabricating nano-dot memory of claim 1, wherein the surface nitridation process comprises a thermal nitridation process.

3. The method of fabricating nano-dot memory of claim 2, wherein the thermal nitridation process is performed at a temperature in a range of 650° C. to 1000° C.

4. The method of fabricating nano-dot memory of claim 2, wherein the thermal nitridation process is performed for 10 minutes to 90 minutes.

5. The method of fabricating nano-dot memory of claim 1, wherein the surface nitridation process comprises a plasma nitridation process.

6. The method of fabricating nano-dot memory of claim 1, wherein the step of nitridizing the nano-dots comprises exposing the nano-dots to a nitrogen-containing gas.

7. The method of fabricating nano-dot memory of claim 6, wherein the step of nitridizing the nano-dots includes heating the nano-dots to a temperature in a range of 300° C. to 600° C.

8. The method of fabricating nano-dot memory of claim 1, wherein the nano-dots comprise silicon or germanium.

9. A method of fabricating a charge storage layer for a non-volatile memory, comprising:
providing a substrate, wherein the substrate has a tunneling oxide layer formed thereon;
performing a surface nitridation process to nitridize an upper surface of the tunneling oxide layer; and
forming a plurality of nano-dots on the upper surface of the tunneling oxide layer.

10. The method of fabricating the charge storage layer of a nano-dot memory of claim 9, wherein the surface nitridation process comprises a thermal nitridation process.

11. The method of fabricating the charge storage layer of a nano-dot memory of claim 10, wherein the thermal nitridation process is performed at a temperature in a range of 650° C. to 1000° C.

12. The method of fabricating the charge storage layer of a nano-dot memory of claim 10, wherein the thermal nitridation process is performed for 10 minutes to 90 minutes.

13. The method of fabricating the charge storage layer of a nano-dot memory of claim 9, wherein the surface nitridation process comprises a plasma nitridation process.

14. The method of fabricating the charge storage layer of a nano-dot memory of claim 9, further comprising a step of forming a protective layer on surfaces of the nano-dots after forming the nano-dots.

15. The method of fabricating the charge storage layer of a nano-dot memory of claim 14, wherein the step of forming the protective layer comprises exposing the nano-dots to a nitrogen-containing gas to nitridize the surfaces of the nano-dots.

16. The method of fabricating the charge storage layer of a nano-dot memory of claim 15, wherein a temperature for nitridizing the surfaces of the nano-dots is between 300° C. and 600° C.

17. The method of fabricating the charge storage layer of a nano-dot memory of claim 9, wherein the nano-dots comprise silicon or germanium.
